(19) United States
(12) Patent Application Publication
(10) Pub. No.: US 2025/0040452 A1
(43) Pub. Date: Jan. 30, 2025

(54) CONTINUOUS LONG JOSEPHSON JUNCTION LOGIC GATE SYSTEM

(71) Applicant: NORTHROP GRUMMAN SYSTEMS CORPORATION, FALLS CHURCH, VA (US)

(72) Inventor: JOSHUA A. STRONG, Ellicott City, MD (US)

(21) Appl. No.: 18/358,603

(22) Filed: Jul. 25, 2023

(51) Int. Cl. H10N 69/00; H10N 60/01; H10N 60/12

(52) U.S. Cl. CPC H10N 69/00; H10N 60/0912; H10N 60/12

(57) ABSTRACT

One example includes a long Josephson junction gate system that includes a continuous long Josephson junction. The continuous long Josephson junction includes a dielectric layer, an electrode layer formed on the dielectric layer and extending along a soliton propagation direction on the dielectric layer, and a dielectric oxide layer formed on the electrode layer and extending along the soliton propagation direction. The continuous long Josephson junction also includes a metallic signal layer formed on the dielectric oxide layer and extending along the soliton propagation direction entirely over the dielectric oxide layer. The arrangement of the continuous long Josephson junction can be approximated by a repeating sequence of a grounded Josephson junction and an inductor to provide a critical current and inductance that define a soliton energy of a soliton propagating in the continuous long Josephson junction.

### TECHNICAL FIELD

The present invention relates generally to computer systems, and specifically to a continuous long Josephson junction logic gate system.

### BACKGROUND

Superconducting digital technology has provided computing and/or communications resources that benefit from unprecedented high speed, low power dissipation, and low operating temperature. Superconducting digital technology has been developed as an alternative to CMOS technology, and typically comprises superconductor based single flux superconducting circuitry, utilizing superconducting Josephson junctions, and can exhibit typical signal power dissipation of less than 1 nW (nanowatt) per active device at a typical data rate of 20 Gb/s (gigabytes/second) or greater, and can operate at temperatures of around 4 or fewer Kelvin.

The propagation of data in superconducting systems can be based on the propagation of pulses, such as resulting from the triggering of Josephson junctions in response to a current through the Josephson junction exceeding a critical current threshold. In one example, the pulses generated from the triggering of a Josephson junction can be discrete and timed to propagate along a Josephson transmission line, such as based on a bias provided at individual phases of a clock signal. As another example, the pulse can propagate as a soliton along a long Josephson junction. A long Josephson junction can be fabricated as discrete superconducting quantum interference devices (SQUIDs) having a set of Josephson junctions separated by an inductor. The sequence of multiple discrete SQUIDs can thus propagate the soliton based on the Josephson junctions having a low critical current with a minimal inductance therebetween.

### SUMMARY

One example includes a long Josephson junction gate system that includes a continuous long Josephson junction. The continuous long Josephson junction includes a dielectric layer, an electrode layer formed on the dielectric layer and extending along a soliton propagation direction on the dielectric layer, and a dielectric oxide layer formed on the electrode layer and extending along the soliton propagation direction. The continuous long Josephson junction also includes a metallic signal layer formed on the dielectric oxide layer and extending along the soliton propagation direction entirely over the dielectric oxide layer. The arrangement of the continuous long Josephson junction can be approximated by a repeating sequence of a grounded Josephson junction and an inductor to provide a critical current and inductance that define a soliton energy of a soliton propagating in the continuous long Josephson junction.

Another example includes a method for fabricating a long Josephson junction logic gate system comprising forming a continuous long Josephson junction. Forming the continuous long Josephson junction includes forming an electrode layer on the dielectric layer, forming a dielectric oxide layer on the electrode layer, and forming a metallic signal layer over the dielectric oxide layer. The method also includes etching at least the metallic signal layer to a width along a soliton propagation direction entirely over at least a portion of the dielectric oxide layer to provide an arrangement of the continuous long Josephson junction that is approximated by a repeating sequence of a grounded Josephson junction and an inductor to provide a critical current and an inductance that defines a soliton energy of a soliton propagating in the continuous long Josephson junction based on the width.

Another example includes a long Josephson junction gate system comprising a continuous long Josephson junction, the continuous long Josephson junction. The continuous long Josephson junction includes a dielectric layer and an electrode layer formed on the dielectric substrate and extending along a soliton propagation direction on the dielectric layer. The continuous long Josephson junction also includes a dielectric oxide layer formed on the electrode layer and extending along the soliton propagation direction, and a metallic signal layer formed on the dielectric oxide layer and extending along the soliton propagation direction entirely over the dielectric oxide layer at a length of N continuous long Josephson junction portions of approximately equal length. Each of the continuous long Josephson junction portions can be approximated by a structure of a grounded Josephson junction and an inductor to provide a portion critical current and a portion inductance, such that the arrangement of the continuous long Josephson junction has a critical current that is a sum of the portion critical current of each of the N continuous long Josephson junction and an inductance that is a sum of the portion inductance of each of the N continuous long Josephson junction.

### BRIEF DESCRIPTION OF THE DRAWINGS

FIG. 1 illustrates an example of a long Josephson junction logic gate system.

FIG. 2 illustrates an example circuit diagram of a long Josephson junction.

FIG. 3 illustrates an example diagram of long Josephson junctions.

FIG. 4 illustrates an example diagram of fabricated long Josephson junctions.

FIG. 5 illustrates an example of a long Josephson junction crossing.

FIG. 6 illustrates an example of a method for fabricating a continuous long Josephson junction logic gate system.

### DETAILED DESCRIPTION

The present invention relates generally to computer systems, and specifically to a continuous long Josephson junction logic gate system. The continuous long Josephson junction logic gate system can be fabricated to include continuous long Josephson junctions. As described herein, a continuous long Josephson junction is formed from patterning an electrode layer on a dielectric layer, a dielectric oxide layer over the electrode layer, and a metallic signal layer over the dielectric oxide layer. The electrode layer, the dielectric oxide layer, and the metallic signal layer can each extend continuously along a soliton propagation direction. As described herein, the continuous long Josephson junction can correspond in function to a long Josephson junction that includes multiple discrete long Josephson junction portions, with each discrete long Josephson junction portion being fabricated with round Josephson junctions. Therefore, the continuous long Josephson junction and the discrete long Josephson junction portions can each exhibit a defined critical current and a defined inductance to propagate a soliton having a defined soliton energy.

To provide the similar characteristics of a discrete long Josephson junction, the continuous long Josephson junction can have a width along the soliton propagation direction that is selected to provide an approximately equal defined critical current and inductance of the discrete long Josephson junction portion. Accordingly, the continuous long Josephson junction can operate approximately the same as a long Josephson junction formed from discrete long Josephson junction portions while providing a simpler manner of fabrication and routing on a superconducting integrated circuit (IC). Furthermore, plasma oscillations can be mitigated in the continuous long Josephson junction relative to a typical long Josephson junction formed from discrete long Josephson junction portions of comparable circuit characteristics.

As an example, the continuous long Josephson junction can be fabricated as having N contiguous portions of approximately equal length. Each of the portions can exhibit the behavior of a discrete long Josephson junction portion, and can have a fraction of the defined critical current and inductance. The width of the metallic signal layer of each of the portions can thus be determinative of the defined critical current and defined inductance of the continuous long Josephson junction. Therefore, each of the N portions can be sized to have 1/N critical current and 1/N inductance of the discrete long Josephson junction portion to provide an approximately equal soliton energy of a soliton propagating on a discrete long Josephson junction. Accordingly, by selecting the width of the metallic signal layer of the continuous long Josephson junction, the continuous long Josephson junction can operate approximately the same as a discrete long Josephson junction to propagate a soliton having an approximately equal soliton energy. As a result, the continuous long Josephson junction can be implemented as part of a logic gate system to provide logic operations with solitons in a superconducting circuit.

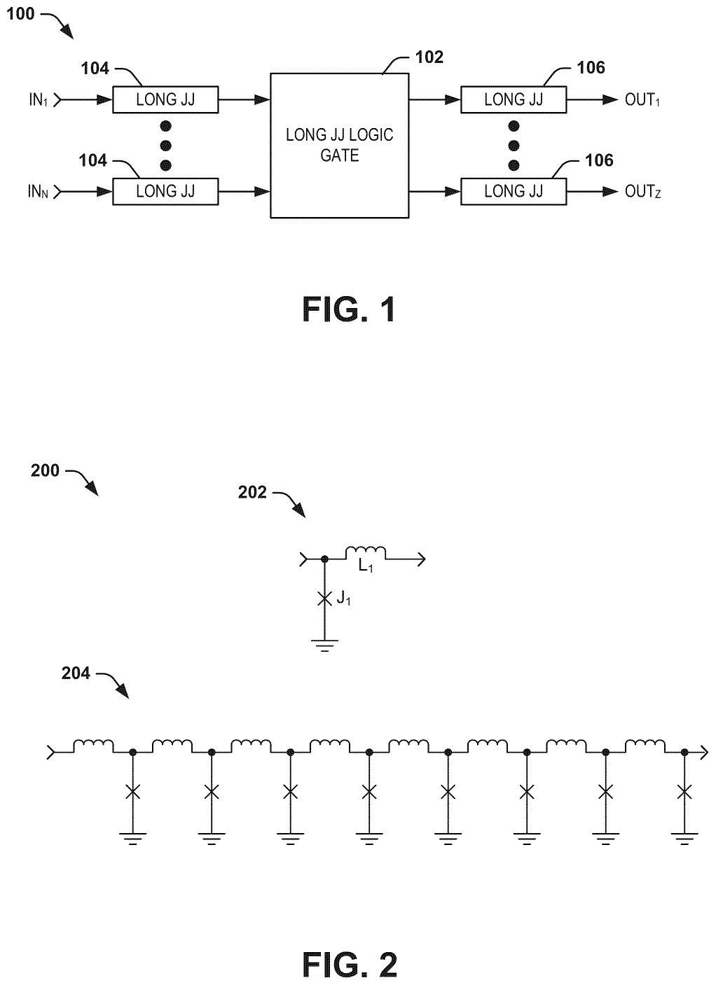

FIG. 1 illustrates an example of a long Josephson junction logic gate system 100. The long Josephson junction gate system 100 can be implemented in any of a variety of superconducting circuits to provide a logical operation (e.g., logic AND, logic OR, logic XOR, etc.). The long Josephson junction gate system 100 includes a long Josephson junction gate 102 that is configured to implement a logic operation in response to input signals IN₁ through IN_{N}, where N is a positive integer greater than one. In the example of FIG. 1, the input signals IN₁ through IN_{N} are provided via input long Josephson junctions 104 to the long Josephson junction gate 102, such that the long Josephson junction gate 102 provides the respective logic operation to provide output signals OUT₁ through OUT_{Z}, where Z is a positive integer greater than one. The output signals OUT₁ through OUT_{Z} are thus provided from the long Josephson junction gate 104 via respective output long Josephson junctions 106.

As described in greater detail herein, the input long Josephson junctions 104, the long Josephson junctions that constitute the long Josephson junction gate 102, and the output long Josephson junctions 106 can be formed as continuous long Josephson junctions. As also described in greater detail herein, continuous long Josephson junction can operate approximately the same as long Josephson junctions formed from discrete long Josephson junction portions while providing a simpler manner of fabrication and routing on a superconducting integrated circuit (IC). Furthermore, plasma oscillations can be mitigated in a continuous long Josephson junction relative to a typical long Josephson junction formed from discrete long Josephson junction portions of comparable circuit characteristics. Accordingly, the long Josephson junction gate system 100 can operate at higher speeds while mitigating the deleterious effects of plasma oscillations.

As described herein, the term “signal” with respect to the input signals IN₁ through INN and the output signals OUT₁ through OUT_{Z} refers to the propagation of a soliton pulse or the lack of a soliton pulse. As an example, the presence of a soliton can correspond to a first logic state (e.g., a logic-one) and the lack of a soliton can correspond to a second logic state (e.g., a logic-zero). However, the logic operation can be predicated on the presence of at least one soliton propagating on a respective at least one of the input long Josephson junctions 104. For example, a soliton provided on one of the input long Josephson junctions 104 can provide an enable, such as to select a long Josephson junction propagation path of another soliton through the long Josephson junction gate 102. As another example, one or more pairs of the input long Josephson junctions 104 and one or more pairs of the output long Josephson junctions 106 can be complements with respect to each other. Therefore, to provide the logic operation via the long Josephson junction gate 102, the input long Josephson junctions 104 can provide at least one soliton to the long Josephson junction gate 102, and the long Josephson junction gate 102 can output at least one soliton via the output long Josephson junctions 106, regardless of the logic inputs and logic outputs of the logic operation.

Based on the formation of the long Josephson junction gate system 100 as the long Josephson junctions input 104 coupled as inputs to the long Josephson junction gate 102, and the output long Josephson junctions 106 coupled as outputs from the long Josephson junction gate 102, then a soliton can propagate through the long Josephson junction gate system 100 along one continuous long Josephson junction. For example, one of the input long Josephson junctions 104, a selected one of the long Josephson junctions in the long Josephson junction gate 102, and one of the output long Josephson junctions 106 can be contiguously coupled to form a contiguous long Josephson junction through the long Josephson junction gate system 100. Therefore, a soliton provided at the respective one of the input long Josephson junctions 104 propagates through the contiguous long Josephson junction and from one of the output long Josephson junctions 106 to another part of the associated superconducting circuit. Accordingly, the entire operation of the long Josephson junction gate system 100 can be implemented by solitons propagating on long Josephson junctions. Examples of the long Josephson junction gate 102 of the long Josephson junction gate system 100 can be found in U.S. Patent Application **/***, ***, Attorney Docket NG (TC)-032587, which is incorporated herein by reference in its entirety.

FIG. 2 illustrates an example circuit diagram 200 of a long Josephson junction. The circuit diagram 200 includes a circuit diagram 202 that corresponds to a discrete portion of a long Josephson junction 204. The circuit diagram 202 includes a grounded Josephson junction J₁ and an inductor L₁ that is coupled to the grounded Josephson junction J₁. In the example of FIG. 2, the circuit diagram 202 of the discrete portion of the long Josephson junction includes an input 206 and an output 208 that each be coupled to other discrete portions of a long Josephson junction to form a complete long Josephson junction that is configured to propagate a soliton, as described herein. While the circuit diagram 202 includes only the grounded Josephson junction J₁ and the inductor L₁, additional inductance and resistance can be included in the discrete long Josephson junction, such as a resistance in parallel with the Josephson junction J₁ and/or an inductance that is representative of the Josephson inductance of the Josephson junction J₁.

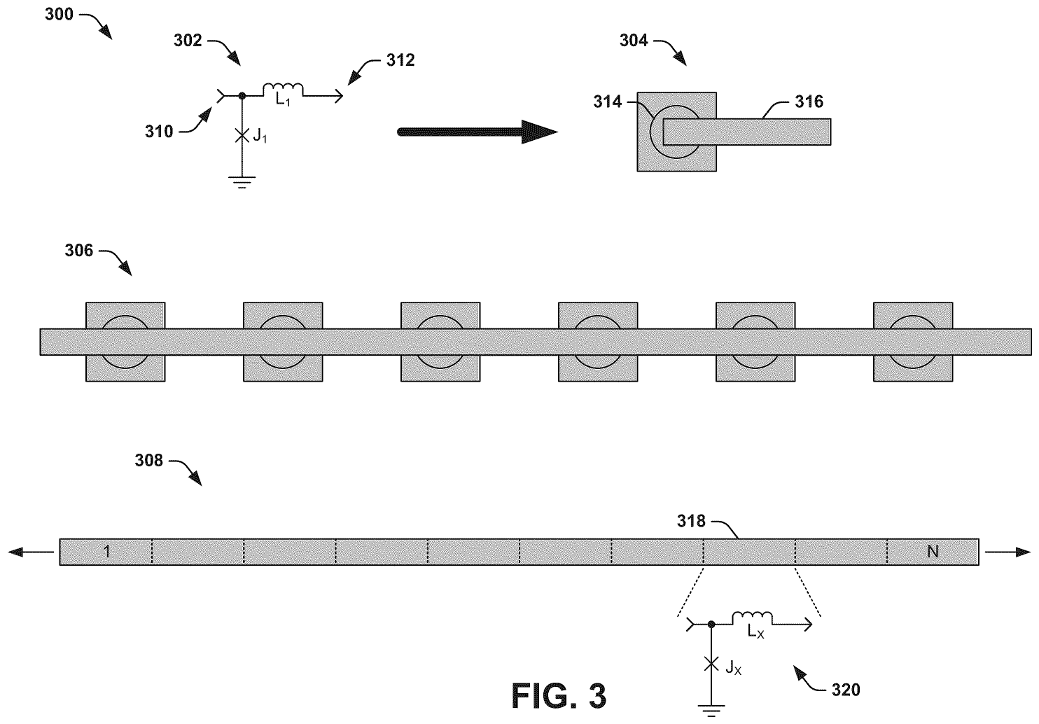

FIG. 3 illustrates an example diagram 300 of long Josephson junctions. The diagram 300 demonstrates a circuit diagram 302 of a discrete long Josephson junction portion, an equivalent fabricated discrete long Josephson junction portion 304, a long Josephson junction 306 formed from discrete long Josephson junction portions (e.g., the discrete long Josephson junction portion 304), and a continuous long Josephson junction 308. As described herein, the circuit diagram 302 can correspond to the circuit diagram of both the discrete long Josephson junction portion 304 and a portion of the continuous long Josephson junction 308.

The circuit diagram 302 can correspond to the circuit diagram 202 in the example of FIG. 2. Therefore, the circuit diagram 302 therefore includes the grounded Josephson junction J₁ and the inductor L₁. Similar to as described in the example of FIG. 2, the circuit diagram 302 can constitute a portion of a long Josephson junction (e.g., the long Josephson junction 204) that propagates a soliton. Therefore, in the example of FIG. 3, the circuit diagram 302 includes an input 310 and an output 312 that each be coupled to other discrete long Josephson junctions to allow for propagation of a soliton along an entire long Josephson junction. In the example of FIG. 3, the discrete long Josephson junction portion 304 includes a circular Josephson junction 314 and an inductor 316 that correspond to the Josephson junction J₁ and the inductor L₁ in the circuit diagram 302. As an example, the circular Josephson junction 314 can include an electrode layer, a metallic electrode layer, and a dielectric oxide therebetween. The inductor 316 can be formed from an inductor layer patterned in an elevated manner relative to the metallic electrode layer to interconnect the Josephson junction J₁ to another Josephson junction of a next discrete Josephson junction portion 304. The long Josephson junction 306 is thus demonstrated in the example of FIG. 3 as having a repeating arrangement of discrete Josephson junction portions that each correspond to the discrete Josephson junction portion 304 having the equivalent circuit diagram 302. Accordingly, the long Josephson junction 306 can have a circuit diagram that is approximately equivalent to the circuit diagram of the long Josephson junction 204.

A soliton propagating on the long Josephson junction 306 can have a given soliton energy Eᵣ that corresponds to generating a soliton pulse at rest. The soliton energy Eᵣ can be expressed as follows:

$${E}_{r} = \frac{8 {I}_{C} {Φ}_{0}}{2 π} \sqrt{\frac{{L}_{J}}{L}} = \frac{8 {Φ}_{0}^{2}}{{( 2 π )}^{2}} \frac{1}{\sqrt{{LL}_{J}}} \qquad Equation 1$$

Where: I_{c} is the critical current of the Josephson junction J₁;
   L is the total linear inductance of the inductor L₁;
   L_{J} is the inductance of the Josephson junction J₁; and
   Φ₀ is a flux quantum.

In Equation 1, the total linear inductance L of the inductor L₁ and the critical current I_{C} each scale with length, and the inductance L_{J} scales inversely with length. Therefore, the soliton energy is independent of length of the long Josephson junction 306. For example, the discrete long Josephson junction portion 304 can have a critical current (I_{c}) of approximately 5 μA and an inductance (L) of approximately 4 pH. Such values can provide for sufficient operation in a long Josephson junction gate system (e.g., the long Josephson junction gate system 100) at a clock frequency of approximately 1 GHz. However, at higher clock frequencies, the operational margins of the discrete long Josephson junction portion 304 can break down, resulting in deleterious operational problems (e.g., plasma oscillations).

To provide for a long Josephson junction system that can operate at higher clock frequency in a long Josephson junction gate system, the long Josephson junction 306 can be replaced by the continuous long Josephson junction 308. As described herein, the continuous long Josephson junction 308 can be fabricated to have substantially the same circuit characteristics as the long Josephson junction 306. Thus, the continuous long Josephson junction 308 can be equally approximated by the circuit diagram of the long Josephson junction 204, and can be designed to have the same defined critical current and same defined inductance to propagate a soliton having an approximately equal soliton energy Er. As an example, the continuous long Josephson junction 308 can be fabricated by forming an electrode layer on a dielectric layer, forming a dielectric oxide layer over the electrode layer, and forming a metallic signal layer over the dielectric oxide layer, such as via a material deposition and etching fabrication technique. The electrode layer, the dielectric oxide layer, and the metallic signal layer can each extend along a soliton propagation direction. The continuous long Josephson junction 308 can have a width that is selected to provide a critical current and an inductance that is approximately equal to the critical current and the inductance of the long Josephson junction 306.

The continuous long Josephson junction 308 can be fabricated such that any arbitrary length can be approximated by the circuit diagram 302. In the example of FIG. 3, the continuous long Josephson junction 308 is demonstrated to have N portions of approximately equal length, demonstrated in the example of FIG. 3 as N=10. Therefore, each of the N portions can correspond to a portion of the continuous long Josephson junction 308 that is approximated by the circuit diagram 302. As described herein, each of the portions of the continuous long Josephson junction 308 can operate as a miniaturized version (1/N) of the discrete long Josephson junction portion 304, and thus collectively operate as the continuous long Josephson junction 308 that is approximated by the circuit diagram of the long Josephson junction 204.

The example of FIG. 3 demonstrates a continuous long Josephson junction portion 318 that corresponds to one of the N portions of the continuous long Josephson junction 308. The circuit diagram that approximates the continuous long Josephson junction portion 318, and thus each of the N continuous long Josephson junction portions, is demonstrated at 320. As demonstrated by the circuit diagram 320, the continuous long Josephson junction portion 318 likewise includes a grounded Josephson junction J_{X} and an inductor L_{X}, similar to the grounded Josephson junction J₁ and the inductor L₁. However, the continuous long Josephson junction portion 312 can be fabricated to have a width that provides a critical current that is 1/N the critical current of the discrete long Josephson junction portion 304 and an inductance that is 1/N the inductance of the discrete long Josephson junction portion 304. However, the N continuous long Josephson junction portions 318 of the continuous long Josephson junction 308 combine critical currents and inductance in an additive manner to integrally form the continuous long Josephson junction 308.

Accordingly, by selecting the width of the metallic signal layer of each of the N continuous long Josephson junction portions 318 of the continuous long Josephson junction 308, the critical current and inductance of each of the N continuous long Josephson junction portions 318 can be selected to provide respective values of 1/N. For example, the width W of a given one of the N portions 318 of the continuous long Josephson junction 308 can be selected to provide a critical current (I_{c}) of approximately 0.5 μA and an inductance (L) of approximately 0.4 pH. Therefore, for N=10, and thus ten contiguous portions of the continuous long Josephson junction 308, the continuous long Josephson junction 308 can exhibit a critical current (I_{c}) of approximately 5 μA and an inductance (L) of approximately 4 pH, and thus an approximately equal critical current and inductance, and therefore soliton energy Eᵣ, as the discrete long Josephson junction portion 304. As a result, the continuous long Josephson junction 308 can operate approximately the same as the discrete long Josephson junction portion 304 having an approximately equal soliton energy Eᵣ.

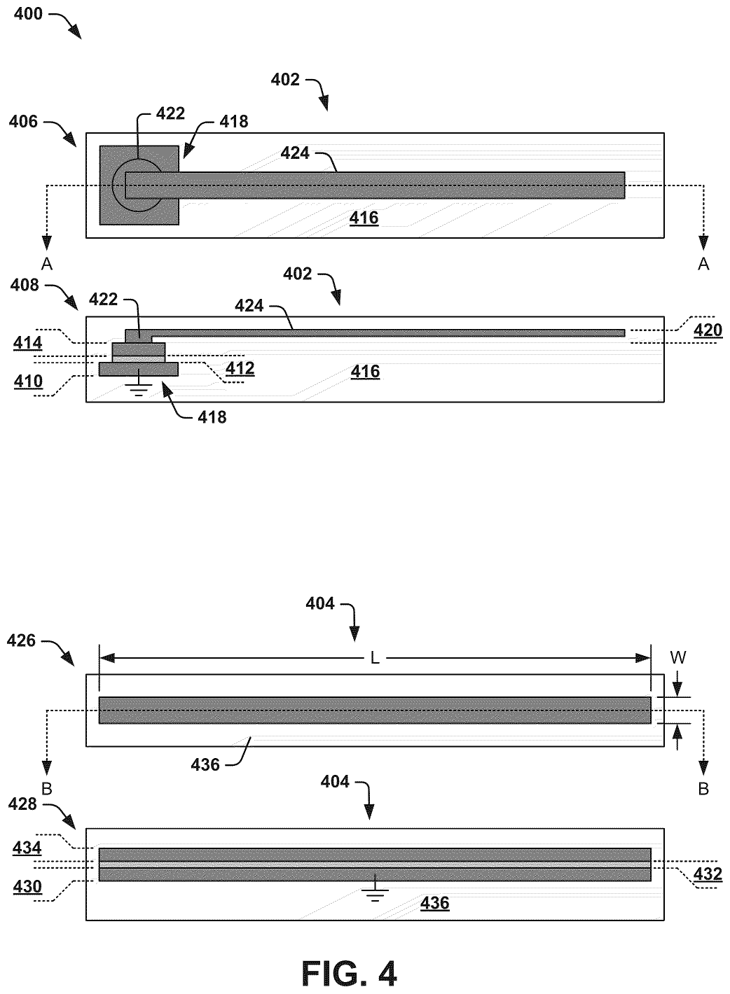

FIG. 4 illustrates an example diagram 400 of fabricated long Josephson junctions. The diagram 400 includes a discrete long Josephson junction portion 402 and a continuous long Josephson junction 404. The discrete long Josephson junction portion 402 can correspond to the discrete long Josephson junction portion 304 in the example of FIG. 3 and the continuous long Josephson junction 404 can correspond to the continuous long Josephson junction 308 in the example of FIG. 3. Therefore, reference is to be made to the example of FIG. 3 in the following description of the example of FIG. 4.

The discrete long Josephson junction portion 402 is demonstrated in a first view 406 that is an overhead view, and a second view 408 that corresponds to a side cross-sectional view taken along “A”. The discrete long Josephson junction portion 402 includes an electrode layer 410, a dielectric oxide layer 412, and a metallic signal layer 414 that are formed in a dielectric layer 416. As an example, the electrode layer 410 can be formed on a portion of the dielectric layer 416 corresponding to a dielectric substrate for the IC. For example, the electrode layer 410 and the metallic signal layer 414 can be formed from any of a variety of superconducting metals (e.g., niobium), and the dielectric oxide layer 412 can be formed from any of a variety of dielectric oxides (e.g., aluminum oxide, ruthenium oxide, or hafnium oxide). As an example, during fabrication, the electrode layer 410 can be formed on the dielectric layer 416, the dielectric oxide layer 412 can be formed on the electrode layer 410, and the metallic signal layer 414 can be formed on the dielectric oxide layer 412, such as based on any of a variety of IC fabrication techniques that provide material deposition and etching. For example, the electrode layer 410 can be grounded, such as formed as electrically coupled to or part of a ground layer, and is thus demonstrated in the example of FIG. 4 as grounded. The portions of the electrode layer 410, the dielectric oxide layer 412, and the metallic signal layer 414 in the discrete long Josephson junction portion 402 can thus correspond to a circular Josephson junction 418 (e.g., the Josephson junction J₁).

In addition, the discrete long Josephson junction portion 402 includes an inductor layer 420 that is formed over the metallic signal layer 414. As an example, the inductor layer 420 can be formed from a superconducting metal. The inductor layer 420 includes a via 422 that extends vertically to the metallic signal layer 414 and an inductor interconnect 424 that can electrically connect the via 422 to another via of a next discrete long Josephson junction portion. The inductor interconnect 424 thus forms an inductor (e.g., the inductor L₁). For example, during fabrication of the discrete long Josephson junction portion 402, the via 422 can be formed on the metallic signal layer 414, and the dielectric material 416 can be implemented to fill the volume around the via 422. Then, the inductor interconnect 424 can subsequently be formed on the via 422 and the dielectric material 416. As described in greater detail herein, the electrical coupling of the inductor interconnect 424 to the via 422 can provide for a bridge arrangement of the inductor interconnect 424 over the metallic signal layer 414. Additionally, other inductor interconnects can be electrically coupled to the via 422, such as to provide an input/output to couple to other circuit devices and/or other discrete long Josephson junctions.

As described above, the portions of the electrode layer 410, the dielectric oxide layer 412, and the metallic signal layer 414 in the discrete long Josephson junction portion 402 can correspond to the circular Josephson junction 418 (e.g., the Josephson junction J₁). The circular Josephson junction 418 can provide for critical current (I_{c}) and inductance (L_{J}) that is sufficient to operate in a long Josephson junction gate system having a given clock frequency, such as 1 GHz. For example, the discrete long Josephson junction portion 402 can have a critical current (I_{c}) of approximately 5 μA and an inductance (L) of approximately 4 pH. However, the operating margins of the discrete long Josephson junction portion 402 can begin to fail at higher clock frequencies. In order to achieve better operating margins at higher clock frequencies, the critical current and inductance of the discrete long Josephson junction portion 402 would need to decrease. However, to decrease the critical current and inductance, the circular Josephson junctions 418 would be required to have dimensions that are smaller than feasible for conventional fabrication techniques.

The continuous long Josephson junction 404 is demonstrated in a first view 426 that is an overhead view, and a second view 428 that corresponds to a side cross-sectional view taken along “B”. The continuous long Josephson junction 404 includes an electrode layer 430, a dielectric oxide layer 432, and a metallic signal layer 434 that are formed in a dielectric layer 436. Similar to as described above, the electrode layer 430 can be formed on a portion of the dielectric layer 436 corresponding to a dielectric substrate for the IC. Also similar to as described above, the electrode layer 430 and the metallic signal layer 434 can be formed from any of a variety of superconducting metals (e.g., niobium), and the dielectric oxide layer 432 can be formed from any of a variety of dielectric oxides (e.g., aluminum oxide, ruthenium oxide, or hafnium oxide). As an example, during fabrication, the electrode layer 430 can be formed on the dielectric layer 436, the dielectric oxide layer 432 can be formed on the electrode layer 430, and the metallic signal layer 434 can be formed on the dielectric oxide layer 432, such as based on any of a variety of integrated circuit fabrication techniques. For example, at least the dielectric oxide layer 432 and the metallic signal layer 434 can be etched to the desired dimensions. For example, the electrode layer 430 can be grounded, such as formed as electrically coupled to or part of a ground layer, and is thus demonstrated in the example of FIG. 4 as grounded.

In the example of FIG. 4, the continuous long Josephson junction 404 is demonstrated as having a length “L” and a width “W”. The length L can correspond to a length that includes N equal-length portions that each have the width W. The continuous coupling along the length L of the electrode layer 430, the dielectric oxide layer 432, and the metallic signal layer 434 can provide for continuous tunneling and inductance along the entire length L, thus providing for a circuit function of the that is approximated by the circuit diagram of the long Josephson junction 202. Therefore, as described above in the example of FIG. 3, each of the N equal-length portions of the continuous long Josephson junction 404 can be approximated by the circuit diagram 320, and can thus include the Josephson junction J_{X} and the inductor L_{X}.

As described above, the width W of each of the N portions of the continuous long Josephson junction 404 can be selected to provide a given critical current and inductance of the respective portion of the continuous long Josephson junction 404 of a given length. Therefore, the width W can be selected to provide for a critical current and inductance that are each 1/N the respective critical current and inductance of the discrete long Josephson junction portion 402.

Similar to as described above in the example of FIG. 3, the width W of a given one of the N portions of the continuous long Josephson junction 404 can be selected to provide a critical current (I_{c}) of approximately 0.5 μA and an inductance (L) of approximately 0.4 pH. Therefore, for N=10, and thus ten contiguous portions of the continuous long Josephson junction 404, each having the width W and a length of L/10, then the continuous long Josephson junction 404 can exhibit a critical current (I_{c}) of approximately 5 μA and an inductance (L) of approximately 4 pH, and thus an approximately equal critical current and inductance as the discrete long Josephson junction portion 402. However, because of the fabrication of the continuous long Josephson junction 404 as a three layered contiguous arrangement instead of the circular Josephson junctions 418 and inductor interconnect 424, the continuous long Josephson junction 404 can operate at higher frequencies while still maintaining sufficient operating margins. In other words, the significantly smaller critical current and inductance of the portions of the continuous long Josephson junction 404 provide for improved operational characteristics of the continuous long Josephson junction 404 over the discrete long Josephson junction portion 402 while still supporting a same soliton energy of a propagating soliton as the discrete long Josephson junction portion 402. Furthermore, fabrication of the continuous long Josephson junction 404 can be provided in a much more simple and efficient fabrication process, as opposed to the discrete long Josephson junction portion 402, which can provide for a more efficient routing of the continuous long Josephson junction 402 on an integrated circuit.

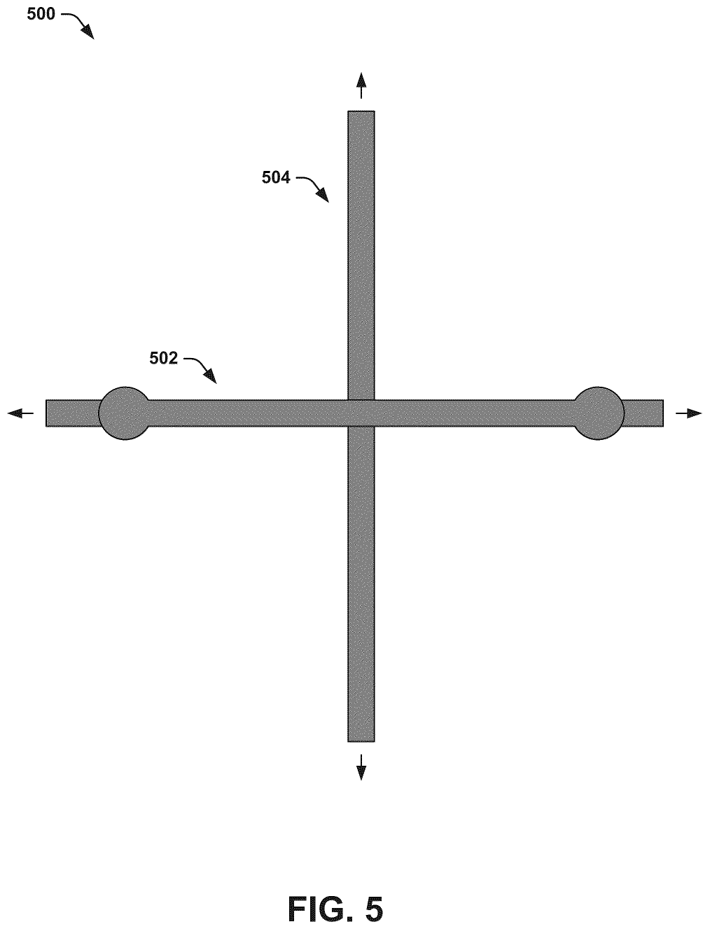

A given IC can include a combination of discrete and continuous long Josephson junctions. FIG. 5 illustrates an example diagram 500 of a long Josephson junction crossing. The diagram 500 includes a long Josephson junction 502 that is formed from discrete long Josephson junction portions and a continuous long Josephson junction 504 that are routed at an orthogonal crossing. The long Josephson junction 502 can correspond to the discrete long Josephson junction 306 in the examples of FIG. 3. The continuous long Josephson junction 504 can correspond to the continuous long Josephson junctions 306 and 404 in the examples of FIGS. 3 and 4, respectively. In the example of FIG. 5, each of the discrete and continuous long Josephson junctions are demonstrated as extending in both soliton propagation directions, such as to form long Josephson junctions.

As described above with reference to the example of FIG. 4, the continuous long Josephson junction 504 can be fabricated such that the electrode layer 430 can be formed on the dielectric layer 436, the dielectric oxide layer 432 can be formed on the electrode layer 430, and the metallic signal layer 434 can be formed on the dielectric oxide layer 432. As also described above with reference to FIG. 4, the discrete long Josephson junction 502 can be formed such that the via 422 can be formed on the metallic signal layer 414, and the inductor interconnect 424 can subsequently be formed on the via 422 and the dielectric material 416 to provide for a bridge arrangement of the inductor interconnect 424 over the metallic signal layer 414. Therefore, to provide a crossing of the long Josephson junction 502 and the continuous long Josephson junction 504, the long Josephson junctions 502 and 504 can be fabricated such that the continuous long Josephson junction 504 extends orthogonally with respect to the long Josephson junction 502 beneath the bridge formed by the inductor interconnect 424. Accordingly, a given IC that includes both long Josephson junctions formed from discrete long Josephson junction portions and continuous long Josephson junctions 502 and 504 can be fabricated with orthogonally-crossed routing based on the fabrication techniques described herein with little complexity.

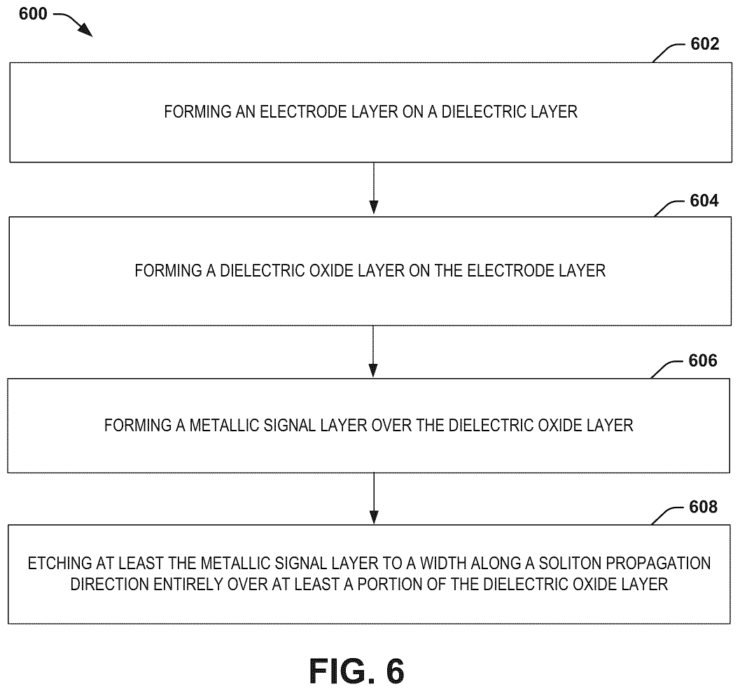

In view of the foregoing structural and functional features described above, a methodology in accordance with various aspects of the disclosure will be better appreciated with reference to FIG. 6. It is to be understood and appreciated that the method of FIG. 6 is not limited by the illustrated order, as some aspects could, in accordance with the present disclosure, occur in different orders and/or concurrently with other aspects from that shown and described herein. Moreover, not all illustrated features may be required to implement a methodology in accordance with an aspect of the present examples.

FIG. 6 illustrates an example of a method 600 for forming a continuous long Josephson junction (e.g., the continuous long Josephson junction 308). At 602, a dielectric layer (e.g., the dielectric layer 416) is formed. At 604, an electrode layer (e.g., the electrode layer 430) is formed on the dielectric layer and extends along a soliton propagation direction on the dielectric layer. At 606, a dielectric oxide layer (e.g., the dielectric oxide layer 432) is formed on the electrode layer and extends along the soliton propagation direction. At 608, at least the metallic signal layer (e.g., the metallic signal layer 434) is etched to a width along a soliton propagation direction entirely over at least a portion of the dielectric oxide layer to provide an arrangement of the continuous long Josephson junction that is approximated by a repeating sequence of a grounded Josephson junction (e.g., the Josephson junction J₁) and an inductor (e.g., the inductor L₁) to provide a critical current and an inductance that defines a soliton energy of a soliton propagating in the continuous long Josephson junction based on the width.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A long Josephson junction gate system comprising a continuous long Josephson junction, the continuous long Josephson junction comprising:
a dielectric layer;
an electrode layer formed on the dielectric layer and extending along a soliton propagation direction on the dielectric layer;
a dielectric oxide layer formed on the electrode layer and extending along the soliton propagation direction; and
a metallic signal layer formed on the dielectric oxide layer and extending along the soliton propagation direction entirely over the dielectric oxide layer, the arrangement of the continuous long Josephson junction being approximated by a repeating sequence of a grounded Josephson junction and an inductor to provide a critical current and inductance that define a soliton energy of a soliton propagating in the continuous long Josephson junction.

2. The system of claim 1, wherein the metallic signal layer has a width of the extension along the soliton propagation direction that is selected to define the critical current and the inductance of the continuous long Josephson junction.

3. The system of claim 1, wherein the metallic signal layer has a length of the extension along the soliton propagation direction of N continuous long Josephson junction portions of approximately equal length in the sequence.

4. The system of claim 3, wherein each of the continuous long Josephson junction portions is approximated as a structure of the grounded Josephson junction and the inductor having a portion critical current and a portion inductance.

5. The system of claim 4, wherein each continuous long Josephson junction portion has a width of the extension along the soliton propagation direction that is selected to define the portion critical current and the portion inductance.

6. The system of claim 5, wherein the portion critical current and the portion inductance is approximately equal to 1/N times the critical current and the inductance of the continuous long Josephson junction.

7. The system of claim 3, wherein the N units corresponding to each continuous long Josephson junction portion is formed as a unitary structure with respect to the electrode layer, the dielectric oxide layer, and the metallic signal layer.

8. A superconducting circuit comprising the long Josephson junction gate system of claim 1.

9. The superconducting circuit of claim 8, further comprising a discrete long Josephson junction comprising:
circular Josephson junctions formed in the electrode layer, the dielectric oxide layer, and the metallic signal layer;
inductors formed from a metal and coupled between pairs of the circular Josephson junctions based on respective vias that extends to portions of the metallic signal layer that form the circular Josephson junctions.

10. The circuit of claim 9, wherein the continuous long Josephson junction and the discrete long Josephson junction are routed in an orthogonal manner such that the continuous long Josephson junction extends beneath the inductor of the discrete long Josephson junction orthogonally with respect to the discrete long Josephson junction.

11. A method for forming a long Josephson junction logic gate system comprising forming a continuous long Josephson junction, wherein forming the continuous long Josephson junction comprises:
forming an electrode layer on a dielectric layer;
forming a dielectric oxide layer on the electrode layer;
forming a metallic signal layer over the dielectric oxide layer; and
etching at least the metallic signal layer to a width along a soliton propagation direction entirely over at least a portion of the dielectric oxide layer to provide an arrangement of the continuous long Josephson junction that is approximated by a repeating sequence of a grounded Josephson junction and an inductor to provide a critical current and an inductance that defines a soliton energy of a soliton propagating in the continuous long Josephson junction based on the width.

12. The method of claim 11, wherein forming the metallic signal layer comprising forming the metallic signal layer at a length of N portions of approximately equal length along the soliton propagation direction.

13. The method of claim 12, wherein each continuous long Josephson junction portion is arranged to approximate the grounded Josephson junction having a defined portion critical current and the inductor having a defined portion inductance.

14. The method of claim 13, wherein etching the metallic signal layer comprises etching the metallic signal layer of each continuous long Josephson junction portion to have a width of the extension along the soliton propagation direction that is selected to provide the defined portion critical current and the defined portion inductance.

15. The method of claim 14, wherein the defined portion critical current and the defined portion inductance is approximately equal to 1/N times the critical current and the inductance, respectively, of the continuous long Josephson junction.

16. A long Josephson junction gate system comprising a continuous long Josephson junction, the continuous long Josephson junction comprising:
a dielectric layer;
an electrode layer formed on the dielectric layer and extending along a soliton propagation direction on the dielectric layer;
a dielectric oxide layer formed on the electrode layer and extending along the soliton propagation direction; and
a metallic signal layer formed on the dielectric oxide layer and extending along the soliton propagation direction entirely over the dielectric oxide layer at a length of N continuous long Josephson junction portions of approximately equal length,
wherein each of the continuous long Josephson junction portions is approximated by a structure of a grounded Josephson junction and an inductor to provide a portion critical current and a portion inductance, such that the arrangement of the continuous long Josephson junction has a critical current that is a sum of the portion critical current of each of the N continuous long Josephson junction and an inductance that is a sum of the portion inductance of each of the N continuous long Josephson junction.

17. The circuit of claim 16, wherein each continuous long Josephson junction portion has a width of the extension along the soliton propagation direction that is selected to define the portion critical current and the portion inductance, wherein the portion critical current and the portion inductance is approximately equal to 1/N times the critical current and the inductance of the continuous long Josephson junction.

18. The circuit of claim 16, wherein the metallic signal layer has a width of the extension along the soliton propagation direction that is selected to define the critical current and inductance of the continuous long Josephson junction.

19. The circuit of claim 16, wherein each continuous long Josephson junction portion has a width of the extension along the soliton propagation direction that is selected to define the portion critical current and the portion inductance.

20. The circuit of claim 16, further comprising a discrete long Josephson junction comprising:
circular Josephson junctions formed in the electrode layer, the dielectric oxide layer, and the metallic signal layer;
inductors formed from a metal and coupled between pairs of the circular Josephson junctions based on respective vias that extends to portions of the metallic signal layer that form the circular Josephson junctions, wherein the continuous long Josephson junction and the discrete long Josephson junction are routed in an orthogonal manner such that the continuous long Josephson junction extends beneath the inductor of the discrete long Josephson junction orthogonally with respect to the discrete long Josephson junction.
